(19) United States
(12) Patent Application Publication
(10) Pub. No.: US 2008/0142078 A1
(43) Pub. Date: Jun. 19, 2008

(54) Optical concentrators having one or more spot focus and related methods

(76) Inventor: Richard L. Johnson, Suffolk, VA (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 11/904,617

(22) Filed: Sep. 27, 2007

Related U.S. Application Data
(60) Provisional application No. 60/848,722, filed on Sep. 30, 2006.
(60) Provisional application No. 60/848,721, filed on Sep. 30, 2006.

(51) Int. Cl. H01L 31/04; G02B 5/10

(52) U.S. Cl. 136/259; 359/853

(57) ABSTRACT

The present invention provides optical concentrators having one or more spot focus (point, region, area, for example), preferably plural spot foci, provided by one or more optic systems. Other aspects of the present invention provides optical concentrators having self refrigeration devices.

### CROSS REFERENCE TO RELATED APPLICATIONS

The present application claims priority to U.S. Provisional Application No. 60/848,722 filed Sep. 30, 2006 and U.S. Provisional Application No. 60/848,721 filed Sep. 30, 2006, the entire contents of which are both incorporated herein by reference.

### TECHNICAL FIELD

The present invention is directed to optical concentrators, optical concentrator systems, and related methods such as those for solar applications that receive incident light and concentrate the light onto a target, such as a photovoltaic target or a target to be heated. In particular, the present invention is directed to optical concentrators with one or more spot focus and related systems and methods.

### BACKGROUND

U.S. Pat. No. 4,169,738 discloses conventional linear optical concentrators that include non-coplanar receivers. FIG. 1 of the present application schematically represents the '738 design and similar designs as including two receivers, 81 and 82, arranged back to back at the base of a trough 80 and parallel to the optical axis. This effectively provides a two-sided receiver. As a direct consequence, unfortunately, the focus of the trough 80 must be such that the trough 80 profile has a large height/width ratio for designs that provide large concentration ratios (i.e. a large ratio between the width of the trough aperture and the height of the receivers, 81 and 82).

Large height/width ratios are not as problematic if such optical concentrators are deployed as part of a fixed array on a panel that articulates as a whole. However, as shown in FIG. 2 of the present application, such conventional designs are unsuitable for use as individually articulated modules. In particular troughs, 83 and 85 freely rotate equally about pivots, 84 and 87, respectively, until the top side of trough 83 impinges on the sidewall of trough 83 indicated by collision zone 86. The rotation angle at which this occurs is a function of the height/width ratio of the troughs and the separation distance between them. In order to space the troughs so as to eliminate the collision requires a separation between the troughs dₛ that is on the order of the trough width dₐ. This separation results in low overall area efficiency for the concentrator system that is not suitable for applications with limited area.

The location of the two receivers, 81 and 82, at the base of the trough 80 limits self-refrigeration. Whereas the location does provide a direct thermal path to the back of the trough 80 where additional convective fins may be employed, the thermal load on the receiver planes is conducted toward the trough base through a relatively narrow interface. Such narrow interfaces generally have a higher thermal resistance. This increases the change in temperature between the receivers and the self-refrigerating device(s) tending to result in a higher operating temperature of the receivers and decreasing the efficiency of the receivers.

U.S. Pat. No. 4,269,168 relates to concentrating modules that focus light in two dimensions and which are generally referred to as point concentrators. The '168 design discloses methods of concentrating solar radiation onto stationary receivers while allowing the concentrating elements (i.e., cover, reflectors, etc.) to articulate about a common axis. FIG. 3 of the present application reproduces FIG. 3 of the '168 patent and shows the use of plural receivers 96 within a concentrator module 92, the use of multiple surfaces 98, and the use of a transparent cover material 94 to encapsulate the reflectors. The modules described in the '168 patent are designed primarily as a heat transfer system and not a photovoltaic system. Self-refrigeration is thus not a concern.

Certain kinds of devices, such as those with individually articulating concentrators, utilize a low overall height for the optical component, so that the concentrators can articulate past each other freely. These devices are described in U.S. patent application Ser. No. 11/454,441, filed on Jun. 15, 2006 and entitled “Planar Concentrating Photovoltaic Panel With Individually Articulating Concentrator Elements” and U.S. patent application Ser. No. 11/654,256, filed on Jan. 17, 2007, and entitled “Concentrated Solar Panel and Related Systems and Methods,” which are commonly-owned by the assignee of record of the present application and which are incorporated by reference herein in their entirety.

### SUMMARY

The present invention provides optical concentrators having one or more spot focus (point, region, area, for example), preferably plural spot foci, provided by one or more optic systems. Exemplary concentrators in accordance with the present invention preferably comprise a first axis of concentration and a second axis of concentration whereby the second axis of concentration is substantially orthogonal to the first axis of concentration, and an optical axis substantially orthogonal to both first and second axes of concentration. In addition exemplary concentrators in accordance with the present invention preferably comprise a first concentrating optic providing one or more line foci substantially parallel to the first axis of concentration, a second concentrating optic providing one or more line foci substantially parallel to the second axis of concentration, one or more optional third concentrating optics providing concentration in both the first and second axes of concentration, and one or more receivers to absorb the concentrated optical energy. The first concentrating optic preferably provides the first entrance aperture comprising one or more substantially transparent refractive media such as a cylindrical Fresnel lens. The second concentrating optic preferably comprises one or more reflecting surfaces each having a respective line focus at an intermediate position between a top and bottom of a volume under concentrated illumination. The second concentrating optic is preferably arranged to the first concentrating optic so that in combination they provide one or more spot foci at an intermediate position between a top and bottom of a volume under concentrated illumination. Each of the one or more third concentrating optics preferably has an entrance aperture arranged proximal to a spot focus provided by the first and second concentrating optics and an exit aperture proximal to a receiver. Advantageously, positioning a spot focus at such an intermediate position allows distribution of the heat load of the optical concentrator among more than one receiver locations when plural receivers are used. Optical concentrators in accordance with the present invention are preferably designed so the full entrance aperture is active. By active it is meant that, ignoring transmission and reflection losses inherent to suitable optical materials, any ray incident within the perimeter of the entrance aperture and substantially parallel the optical axis is collected by a receiver. Other advantages of optical concentrators in accordance with the present invention include a height to width ratio of individual concentrators favorable to dense packing of such concentrator in arrays of plural concentrators without sacrificing articulation range.

Optical concentrating systems are provided in accordance with the present invention. Such optical concentrating system may be used as solar collectors, for example. Such systems concentrate light onto a device located near the focus of the optical system for the purpose of converting absorbed radiation into another useful form of energy such as electricity by a photovoltaic cell or heat by an energy absorber or other transducer. Optical concentrators and devices in accordance with the present invention relate to systems that concentrate light in plural dimensions and in plural stages of concentration and may be generally referred to as compound concentrators. Additional optics may be used in parallel or series in accordance with the present invention.

High area efficient optical concentrators are also provided in accordance with the present invention. Such optical concentrators are preferably designed to minimize blocking of rays parallel to the optical axis and incident on the aperture of a first concentrating optic thereby maximizing the area efficiency of the optical concentrator. Such optical concentrators provide high area efficiency by being designed to be compact and by preferably comprising aperture(s) that allow plural optical concentrators to be provided in an area with minimal spacing.

Systems comprising plural optical concentrators are also provided in accordance with the present invention. Preferably, plural optical concentrators are arranged in arrays, preferably parallel arrays wherein respective optical axes are preferably spaced apart by a distance that allows individual concentrators to articulate without colliding and/or interfering with adjacent concentrators. Individual optical concentrators can be articulated about two or more pivot axes while not impinging on adjacent optical concentrators articulating in kind about their respective pivot axes. Optical concentrators in accordance with the present invention are preferably designed with a height/width ratio suitable for such dense arrangement thereby allowing a high area efficient system.

Devices that use self-refrigerating methods to dissipate excess thermal energy are provided in accordance with the present invention. Devices having high optical radiation concentration in compact packages, specifically those with photovoltaic elements, require dissipation of thermal energy resulting from inefficient conversion of radiation into electricity. Such thermal energy dissipation is achieved in accordance with the present invention, by passive self-refrigerating methods, such as natural convection, for example.

In a representative embodiment, a first concentrating optic focuses incoming radiation to one or more lines, which are subsequently focused to a spot by a second concentrating optic. In the second concentrating optic first and second reflective surfaces are opposed so as to define a volume under optical concentration between such surfaces. In a preferred embodiment, the volume is at least partially defined by a trough, which trough is at least partially defined by the first and second reflective surfaces. A spot focus resulting from the combined concentration of the first concentrating optic and the first reflective surface is proximal to the second reflective surface. Similarly, a spot focus resulting from the combined concentration of the first concentrating optic and the second reflective surface is proximal to the first reflective surface. In accordance with the present invention, one or both focal spots/points are positioned intermediate between the top and bottom of the volume under optical concentration. A first exit aperture is associated with the second reflective surface in a manner effective to capture incident light focused onto the first exit aperture, and a second exit aperture is associated with the first reflective surface in a manner effective to capture incident light focused onto the second aperture. A first receiver element(s) is preferably positioned in optical communication with the first exit aperture and a second receiver element(s) is preferably positioned in optical communication with the second exit aperture. In preferred embodiments, a receiver is located outside the volume under optical concentration. In some embodiments, a receiver is positioned outside the trough. Optionally, one or more third concentrating optic(s) may be used to further concentrate light captured by the first exit aperture as such light travels from an exit aperture to the receiver element(s).

In an aspect of the present invention an optical concentrator is provided. The optical concentrator preferably comprises a body comprising a top and a bottom and comprising an entrance aperture that allows radiation to be concentrated to enter an interior space of the body, an exit that allows concentrated radiation to leave the interior space of the body, the exit positioned at an intermediate position between the top and bottom of the body, and a radiation receiver operatively positioned relative to and in optical communication with the exit; a first concentrating optic comprising a first axis of concentration and plural line foci substantially parallel to the first axis of concentration; and a second concentrating optic comprising a second axis of concentration substantially orthogonal to the first axis of concentration and a line focus substantially parallel to the second axis of concentration, and a reflective surface positioned within the interior space the body, wherein the line foci of the first and second concentrating optics cooperatively provide a region of focused radiation to the exit.

In another aspect of the present invention an optical concentrator is provided. The optical concentrator preferably comprises a body comprising a top, bottom, first end, and second end, an exit that allows concentrated radiation to leave the interior space of the body, the exit positioned at an intermediate position between the top and bottom of the body, and a radiation receiver operatively positioned relative to and in optical communication with the exit; a first concentrating optic comprising a first axis of concentration and plural line foci substantially parallel to the first axis of concentration, the first concentrating optic at least partially defining an entrance aperture that allows radiation to be concentrated to enter an interior space of the body; and a second concentrating optic comprising a second axis of concentration substantially orthogonal to the first axis of concentration and a line focus substantially parallel to the second axis of concentration, and a reflective surface positioned within the interior space the body, wherein the line foci of the first and second concentrating optics cooperatively provide a region of focused radiation to the exit; wherein one of the first and second ends of the body is truncated relative to the entrance aperture.

In yet another aspect of the present invention, a method of concentrating radiation in a solar concentrator is provided. The method comprises the steps of causing solar radiation to impinge a concentrating lens of an optical concentrator; focusing the radiation with the concentrating lens to plural first line foci that impinge on a reflective surface of the optical concentrator; focusing the radiation with the reflective surface to a second line focus orthogonal to the first line foci; and combining the first line foci and the second line focus to provide a spot focus to one or more receivers of the optical concentrator.

### BRIEF DESCRIPTION OF THE DRAWINGS

The accompanying drawings, which are incorporated in and constitute a part of this application, illustrate several aspects of the present invention and together with description of the embodiments serve to explain the principles of the invention. A brief description of the drawings is as follows:

FIG. 1 is a cross-sectional view of a prior art optical concentrator having a two-sided receiver.

FIG. 2 is a cross-sectional view of plural prior art optical concentrators showing in particular articulation restrictions in the form of a collision zone.

FIG. 3 is a perspective view of a prior art optical concentrator showing in particular plural parabolic-like surfaces.

FIG. 4 is a perspective view of an exemplary optical concentrator in accordance with the present invention.

FIG. 5 is a cross-sectional view of the exemplary optical concentrator of FIG. 4 showing in particular a first reflective optic and first and second optional second optics.

FIG. 6 is a schematic cross-sectional view of the second optic for the optical concentrator of FIG. 5.

FIG. 7 is a schematic cross-sectional view of ray traces formed by the exemplary second optic of the optical concentrator of FIG. 5.

FIG. 8 is a cross-sectional view of an alternative embodiment of an exemplary optic for an optical concentrator in accordance with the present invention.

FIG. 9 is a cross-sectional view of another exemplary optic for an optical concentrator in accordance with the present invention.

FIG. 10 is a cross-sectional view of yet another exemplary optic for an optical concentrator in accordance with the present invention.

FIG. 11 is a perspective view of another exemplary optical concentrator in accordance with the present invention.

FIG. 12 is a perspective view of an exemplary first optic of the optical concentrator of FIG. 11.

FIG. 13 is an exploded view of the first optic of FIG. 12.

FIG. 14 is a schematic perspective view of ray traces formed by the exemplary first optic of FIGS. 12 and 13.

FIG. 15 is a schematic perspective view of ray traces formed by another exemplary optic in accordance with the present invention.

FIG. 16 is a side view of an exemplary second optic of the optical concentrator of FIG. 11.

FIG. 17 is a perspective view of the exemplary second optic of FIG. 16.

FIG. 18 is a schematic cross-sectional view of ray traces formed by the exemplary optical concentrator of FIG. 11.

FIGS. 19-28 are schematic views of tertiary optics that can be used with optical concentrators in accordance with the present invention.

FIG. 29 is a perspective view of another exemplary optical concentrator in accordance with the present invention showing in particular self-refrigeration devices.

FIG. 30 is a perspective view of a heat spreader of the optical concentrator of FIG. 29.

FIG. 31 is a perspective view of heat dissipation fins of the optical concentrator of FIG. 29.

FIG. 32 is a perspective view of a receiver assembly of the optical concentrator of FIG. 29.

FIG. 33 is a perspective view of another exemplary optical concentrator in accordance with the present invention.

FIG. 34 is an end view of the optical concentrator of FIG. 33.

FIG. 35 is a side view of the optical concentrator of FIG. 33.

FIG. 36 is a top view of the optical concentrator of FIG. 33.

FIGS. 37 and 38 are top views of exemplary optics that can be used with an optical concentrator in accordance with the present invention.

FIG. 39 is an optical concentrator system comprising first and second optical concentrators.

FIG. 40 is a top view of an array the optical concentrator system of FIG. 39.

FIG. 41 is a side view of an array the optical concentrator system of FIG. 39.

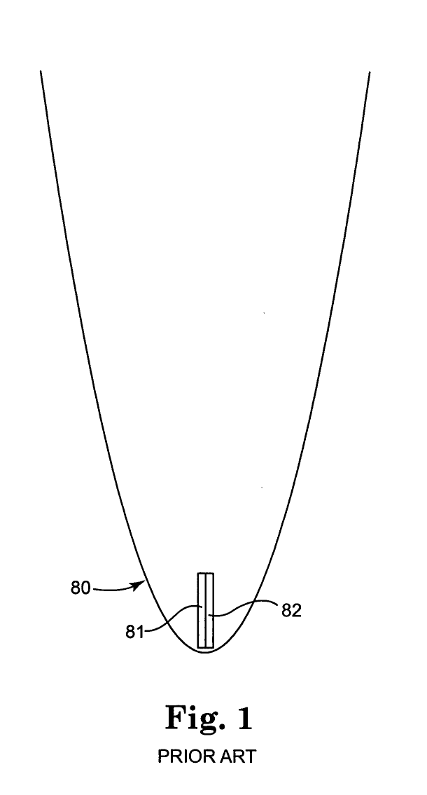

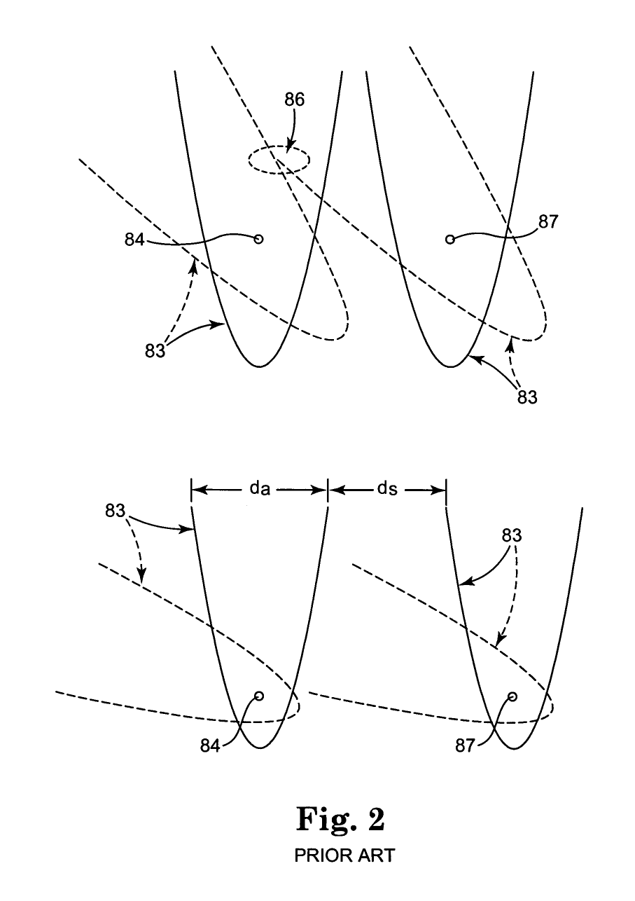

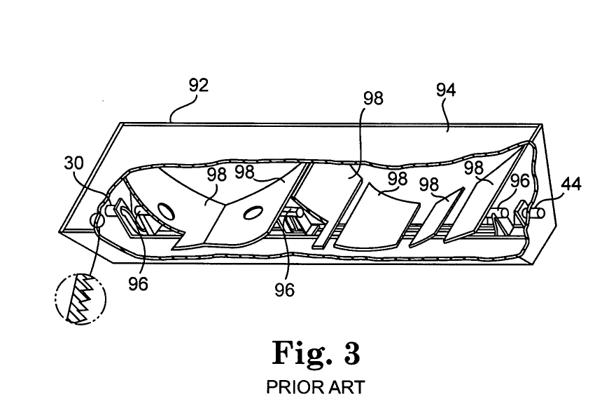

### DETAILED DESCRIPTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention.

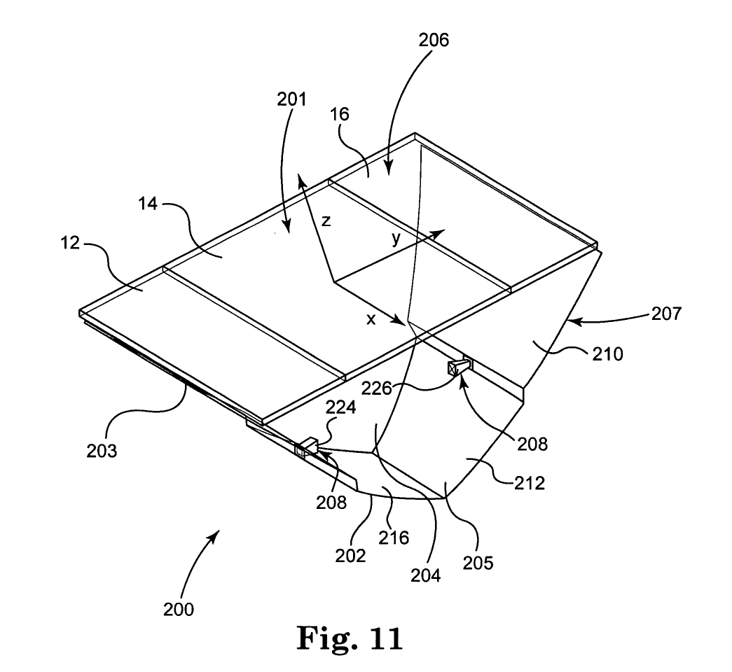

An optical concentrator 200 in accordance with the present invention is illustrated in FIG. 11. Generally, optical concentrator 200 comprises body 202 having entrance aperture 201 to internal space 204. At least a portion of internal space 204 provides a volume under optical concentration. Body 202 comprises top 203 and bottom 205.

As illustrated in FIG. 11, optical concentrator 200 includes first optic system 206, second optic system 207, and optional third optic system 208, which cooperatively function to concentrate incoming radiation to one or more point focus in accordance with the present invention. First, second, and third optic systems are described in turn below.

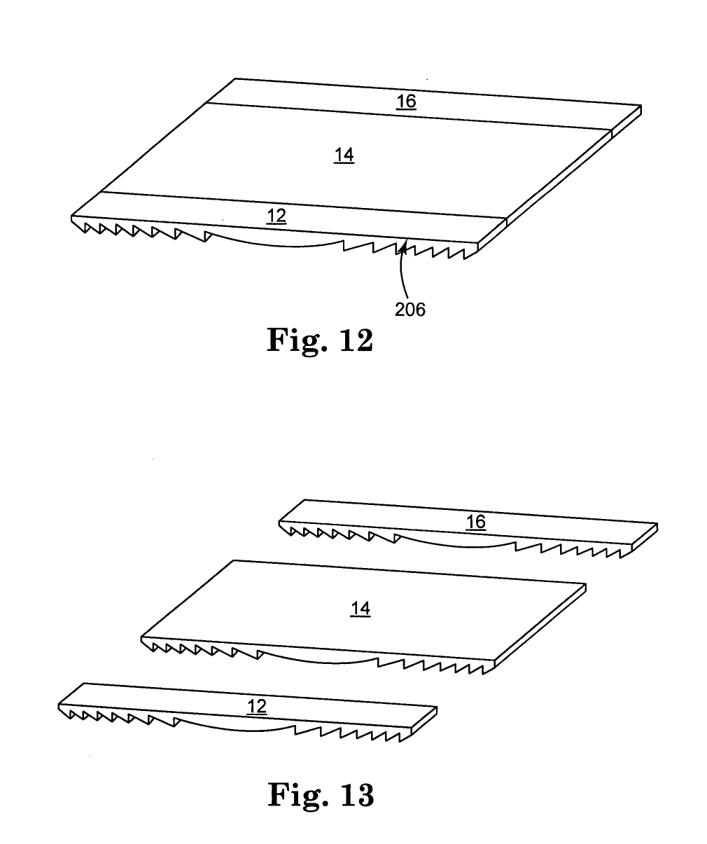

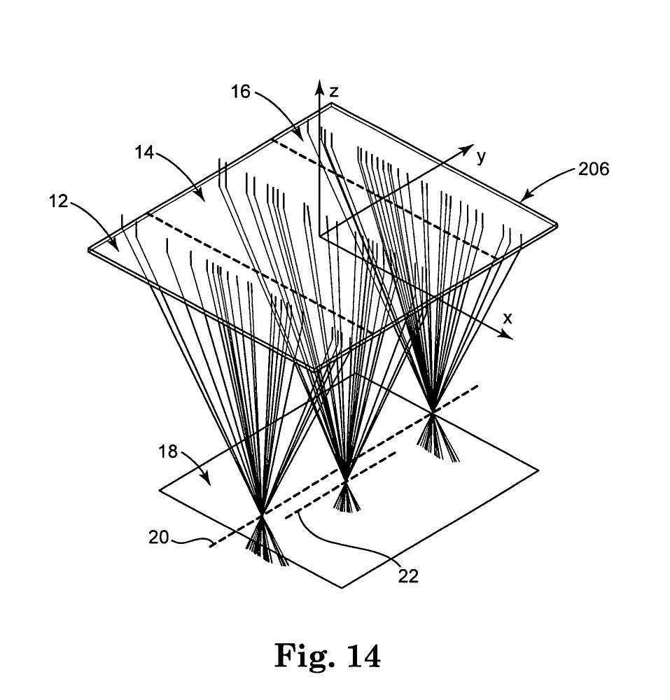

First optic system 206 is shown in a perspective view in FIG. 12 and in an exploded view in FIG. 13. In a preferred embodiment, first optic system 206 comprises a fresnel lens system having an optical axis parallel to the z-axis and a concentrating axis parallel to the x axis. First optic system 206 comprises, as illustrated, a lens system comprising lens portions 12, 14, and 16. Any number of lens portions can be used including a single lens. Lens portions 12 and 16 may be identical if desired. Referring to FIG. 14 lens portions 12 and 16 are preferably designed so rays incident on lens portions 12 and 16 are focused to points along focal line 20 above reference plane 18 that is parallel to the plane of first optic system 206. Lens portion 14 is preferably designed so incident rays are focused to a point along focal line 22 lying on plane 18. Focal lines 20 and 22 may be parallel to the y-axis and plane 18 in some embodiments. In a contemplated embodiment, first optic system 206 preferably comprises one or more cylindrical fresnel lens. In some embodiments, such lenses comprise plural focal lines. Plural focal lines advantageously permit a secondary concentrating optic (described below) to provide vertical discontinuities. These discontinuities provide space required for focused radiation to exit from the volume without reducing the effective collecting aperture. Consequently, in order for the first and second concentrating optic to cooperatively form a spot focus in accordance with the present invention, the focal length of the lens portion located above and to a first side of the discontinuity must be necessarily different than the focal length of the lens portion located above and to a second side of the discontinuity.

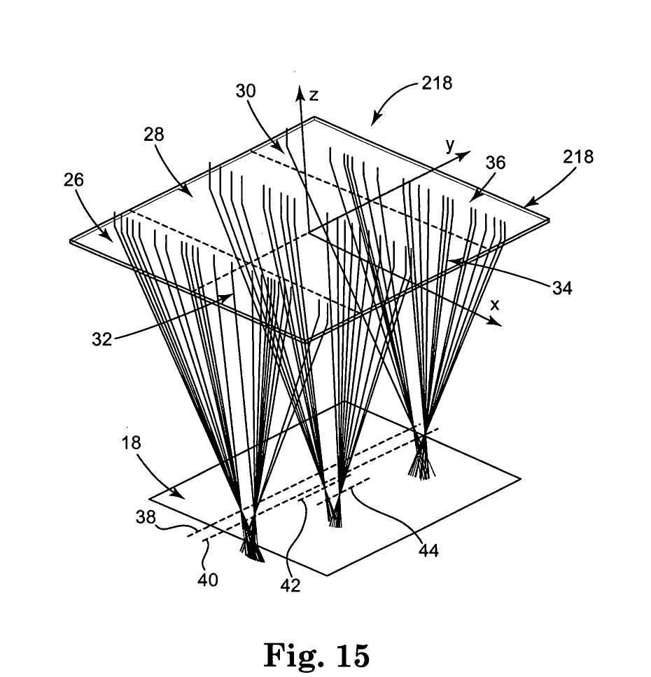

Another exemplary optic system 218 that can be used as a first optic in an optical concentrator such as the optical concentrator 200 is shown in FIG. 15. As shown, optic system 218 comprises lens portions 26, 28, 30, 32, 34, and 36. In some embodiments, regions 26, 30, 32, and 36 are rotationally symmetric as are regions 28 and 34. Regions 26 and 30 are preferably designed so that incident rays are focused along a focal line 38 located above the plane 18. Regions 32 and 36 are preferably designed so that incident rays are focused along a focal line 40 located above the plane 18. Regions 28 and 34 are preferably designed so that incident rays are focused along a focal line 42 and 44 respectively on plane 18. Focal lines 38, 40, 42, and 44 are preferably parallel to the y-axis and plane 18. Focal lines 38 and 40 are preferably equidistant from plane 18. Focal lines 38 and 42 preferably lie along a plane parallel to the y-z plane. Focal lines 40 and 44 preferably lie along a plane parallel to the y-z plane. In a contemplated embodiment, optic system 218 comprises a multi-focal fresnel lens designed as a single element. In an alternative embodiment, one or more lens portion comprises a separate sub-element.

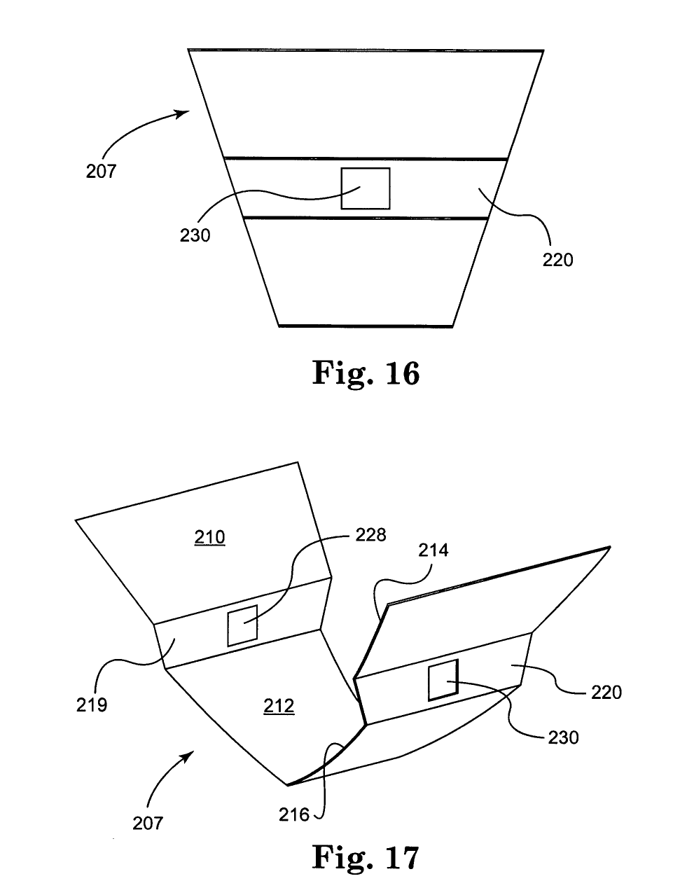

Referring to FIGS. 11, 16, 17, and 18, second optic system 207, as shown, comprises reflective surfaces 210, 212, 214, and 216. Surfaces 210, 212, 214, and 216 preferably comprise parabolic or parabolic-like surfaces. Preferably, the top surfaces 210 and 214 share a common foci with the bottom surfaces 212 and 216, respectively. Preferably, such foci are coincident or near coincident with the opposing side of the second optic. Second optic system 207 is preferably designed according to the first optic systems described below such as first optic system 108 and preferably comprises a reflective trough, having an optical axis parallel to the z-axis and a concentration axis parallel to the y-axis. Second optic system 207 preferably comprises first exit aperture 228 located at first discontinuity 219 and second exit aperture 230 located at second discontinuity 220. First exit aperture 228 and second aperture 230 function as exit apertures for concentrated radiation to leave internal space 204.

Second optic system 207 may be designed to concentrate to any desired number of focal points, spots, or regions. In one exemplary embodiment each half of the trough concentrates to a single focal spot. In another exemplary embodiment, each half of the trough concentrates to two focal spots one from the top surface and one from the bottom surface.

Referring to FIG. 11, optical concentrator 200 also preferably comprises optional third optic system 208 having first optic 224 operatively positioned relative to a first receiver (not shown) and second optic 226 operatively positioned relative to a second receiver (not shown). Preferably, first receiver (not shown) and first optic 224 of the third optic system 208 are positioned at first exit aperture 228 between reflective surface 210 and reflective surface 212. Also, second receiver (not shown) and second optic 226 of the third optic system 208 are positioned at second exit aperture 230 between reflective surface 214 and reflective surface 216.

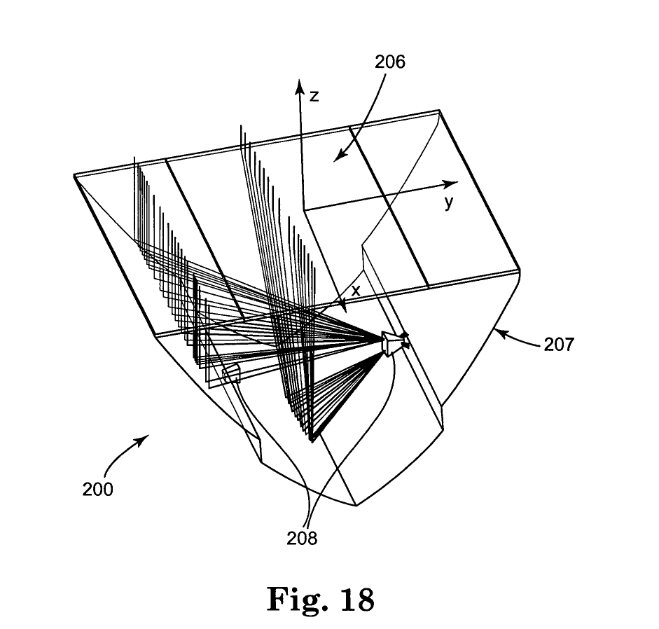

As shown in FIG. 18, incident rays parallel to the optical axis of concentrator 200 are refracted by first optic system 206 and then subsequently reflected by second optic system 207. The first and second optics systems, 206 and 207, are designed so the rays are concentrated in two dimensions and directed toward exit apertures of body 202 where optic elements of the third optics system are positioned. That is, first optic system 206 concentrates incoming radiation to a line. Second optic system 207 also focuses to a line focus, which line focus is orthogonal to first optic system 206. The combination of first optic system 206 and second optic system 207 provides the third optic system 208 with a spot or point focus in accordance with the present invention. Accordingly, the second optic system 207 is preferably designed by considering the focal length of the first optic system 206. For clarity only representative portions of rays are traced and only for one half of the concentrator.

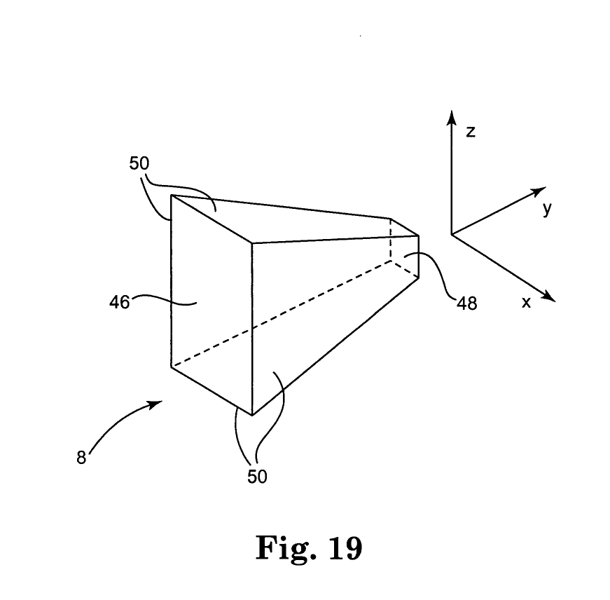

In FIG. 19, exemplary optic 8 is shown and can be used for one or both of the first and second optic, 224 and 226, of third optic system 208. As shown, optic 8 comprises a solid transparent optic element having a generally pyramidal shape with an entrance aperture 46 and an exit aperture 48. Both entrance aperture 46 and exit aperture 48 are preferably parallel to the x-z plane with entrance aperture 46 preferably larger in area than exit aperture 48. Rays are generally concentrated by the surface of entrance aperture 46 toward exit aperture surface 48. Additionally four generally planar side faces 50 preferably total internally reflect rays thereby concentrating such rays toward exit aperture 48. As shown, entrance aperture 46 comprises plural refracting surfaces. Contemplated optics for third optic system 208 preferably comprise plural refracting surfaces and plural total internal reflection surfaces. In some embodiments, the refractive surfaces are bi-conic.

In contemplated embodiments, optics used for third optic system 208 are preferably located inside the volume bounded by the first and second optic systems, 206 and 207 so exit apertures of such optics are preferably at or near a surface of the second optic system 207. In other contemplated embodiments, optics used for third optic system 208 are preferably located outside the volume bounded by the first and second optic systems, 206 and 207 so entrance apertures of such optics are preferably at or near a surface of second optic system 207. In yet another alternative embodiment, any desired portion of an optic used for third optic system 208 may be located inside the volume bounded by the first and second optic systems, 206 and 207.

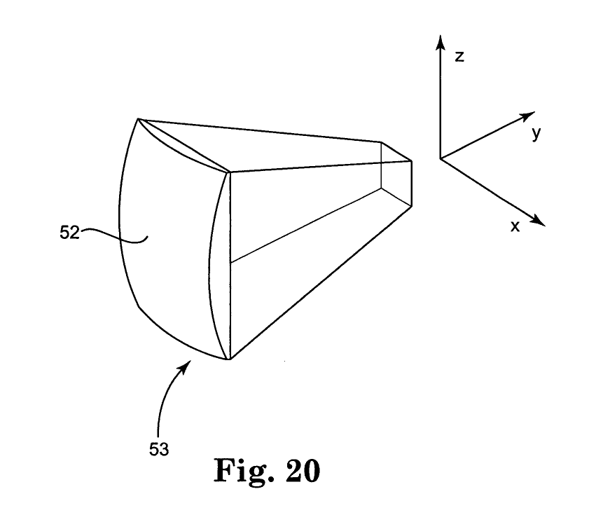

In FIG. 20, another exemplary optic 53 is shown and can be used for one or both of the first and second optic, 224 and 226, of third optic system 208. Optic 53 is similar to optic 8 except optic 53 comprises an entrance aperture surface 52 having a single generally bi-conic surface. The design of optic 53 is beneficial when the concentrated rays from the first and second optic systems, 206 and 208, form a single solid angle at the entrance aperture of optic 53.

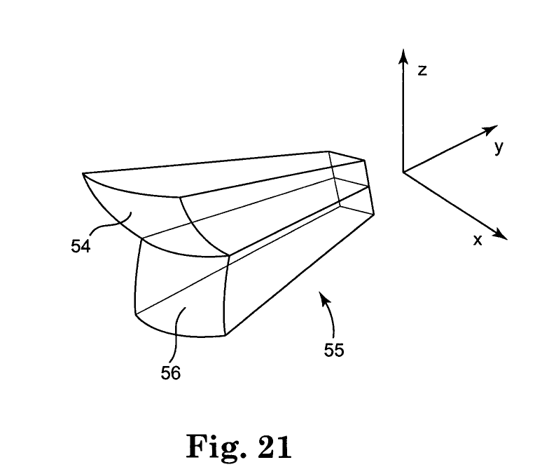

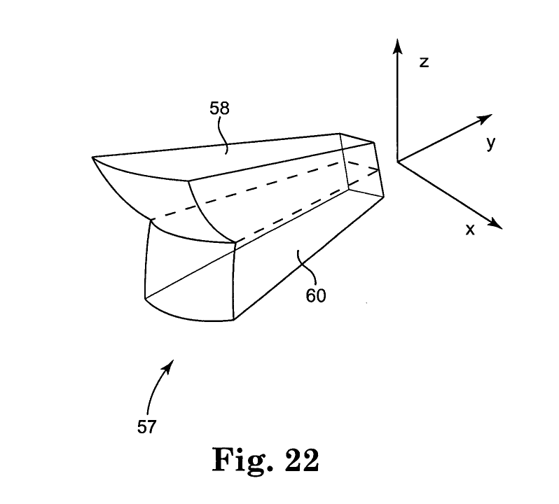

In FIG. 21, another exemplary optic 55 is shown and can be used for one or both of the first and second optic, 224 and 226, of third optic system 208. Optic 55 is similar to optic 8 except optic 55 comprises an entrance aperture surface having first and second generally bi-conic surfaces 54 and 56, respectively. The design of optic 55 is beneficial when the concentrated rays from the first and second optic systems, 206 and 207, form two separate solid angles at the entrance aperture of the optic 55.

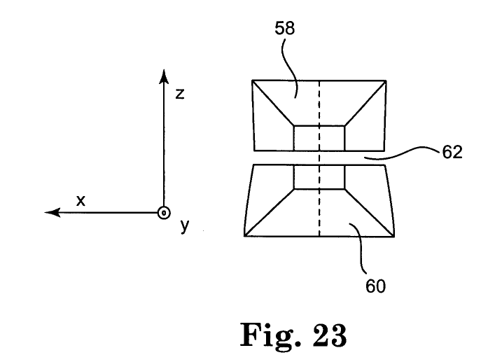

In FIG. 22, another exemplary optic 57 is shown and can be used for one or both of the first and second optic, 224 and 226, of third optic system 208. Optic 57 is similar to optic 8 except optic 55 comprises first and second sub-elements, 58 and 60, each having a single generally bi-conic surface as an entrance aperture, respectively. In one preferred embodiment, sub-elements, 58 and 60, are bonded together with index matching methods, devices and/or apparatus. As shown in FIG. 23, sub-elements, 58 and 60, may also be separated by a region 62 having a lower index of refraction including but not limited to air.

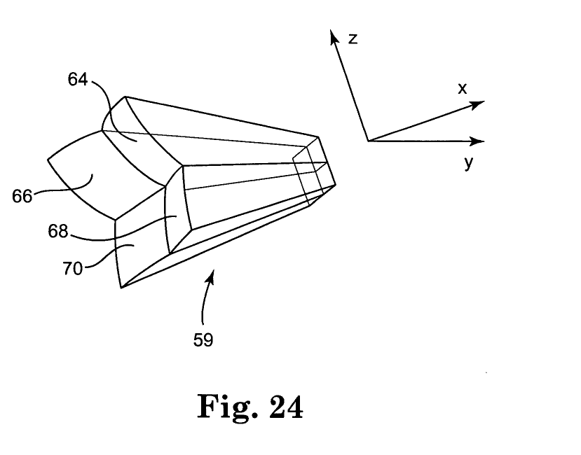

In FIG. 24, another exemplary optic 59 is shown and can be used for one or both of the first and second optic, 224 and 226, of third optic system 208. Optic 59 is similar to optic 8 except optic 59 comprises an entrance aperture surface having four generally bi-conic surfaces 64, 66, 68 and 70. The design of optic 59 is beneficial when the concentrated rays from the first and second optic systems, 206 and 207, form four distinct solid angles at the entrance aperture of the optic 59.

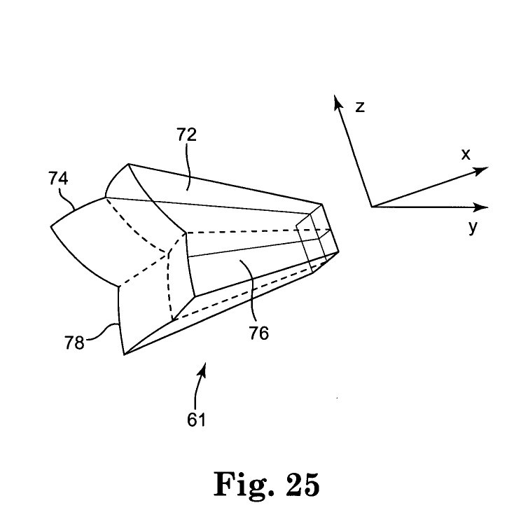

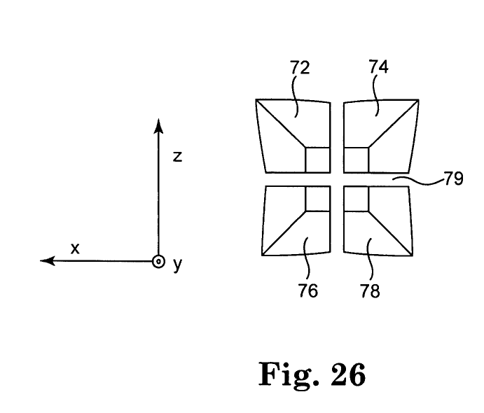

In FIG. 25, another exemplary optic 61 is shown and can be used for one or both of the first and second optic, 224 and 226, of third optic system 208. Optic 61 is similar to optic 8 except optic 61 comprises four sub-elements 72, 74, 76, and 78 each having a single generally bi-conic surface as an entrance aperture respectively. In one preferred embodiment, sub-elements, 72, 74, 76, and 78, are bonded together with index matching methods, devices and/or apparatus. As shown in FIG. 26, sub-elements, 72, 74, 76, and 78, may also be separated by a region 79 having a lower index of refraction including but not limited to air.

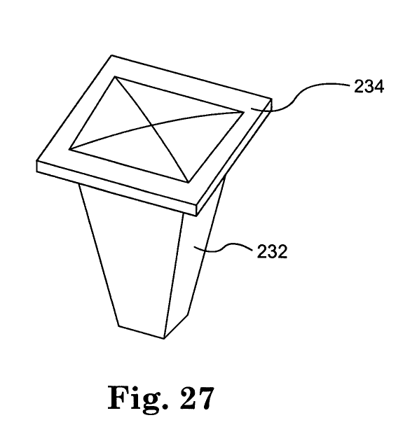

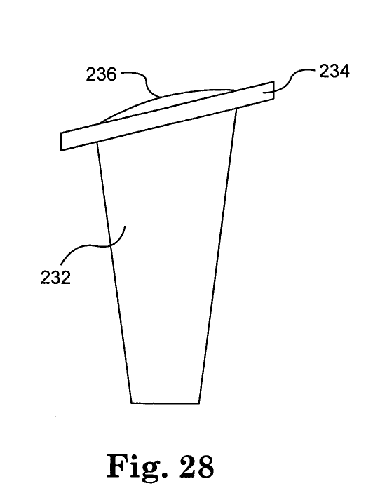

In FIGS. 27 and 28, a perspective view and side view, respectively, of another exemplary optic 232 are shown and can be used for one or both of the first and second optic, 224 and 226, of third optic system 208. Optic 232 is similar to optic 8 and further includes flange 234. Flange 234 is preferably positioned to minimally interfere with optical performance of optic 232. As shown, flange 234 preferably follows the angle of face 236. Flange 234 preferably functions to attach optic 232 to an optical concentrator. Flange may comprise any desired size and shape such as square, rectangular, circular, elliptical, for example.

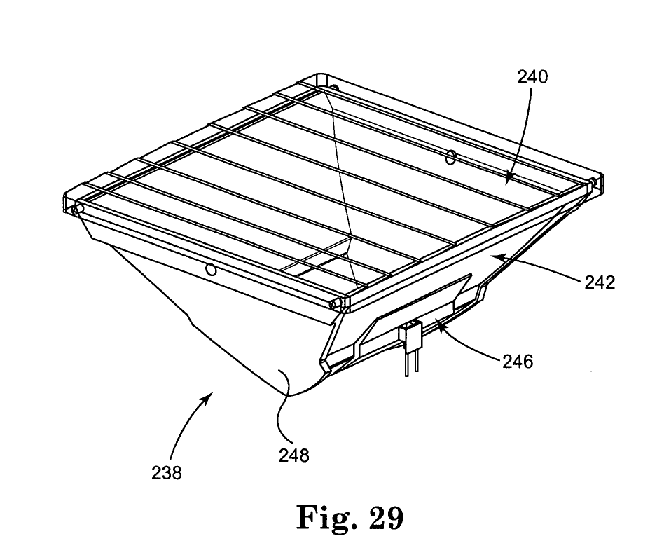

An exemplary self-refrigerating optical concentrator 238 is illustrated in FIG. 29 and is preferably designed to passively dissipate excess thermal energy. Such heat dissipation techniques can be applied to any optical concentrator described herein. Devices, methods, and apparatus utilized for self-refrigeration in accordance with the present invention may include: plural heat spreader elements in thermal contact with receiver elements, plural convective fins arranged around the heat spreader elements, and the like. Contemplated heat spreader elements and/or convective fins are preferably designed to provide heat dissipation to one or more optic systems of an optical concentrator in accordance with the present invention. In some embodiments, a receiver or self-refrigerators are preferably arranged outside the trough of an optical concentrator. The receiver(s) may be in contact directly or indirectly with one or more concentrator optic allowing them to serve as a self-refrigerating mechanisms for the receiver(s). Contemplated receivers can be arranged such that the field of view of the sky of the receiver encompasses a significant portion of the entrance aperture of the first optic.

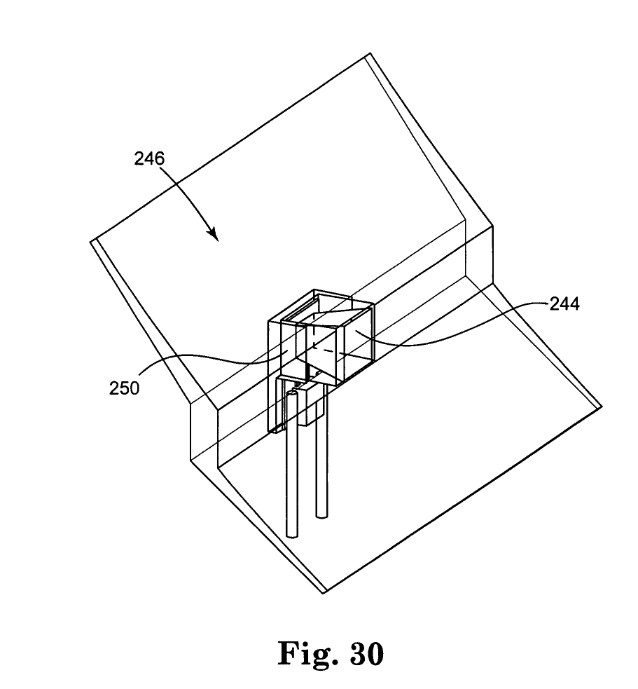

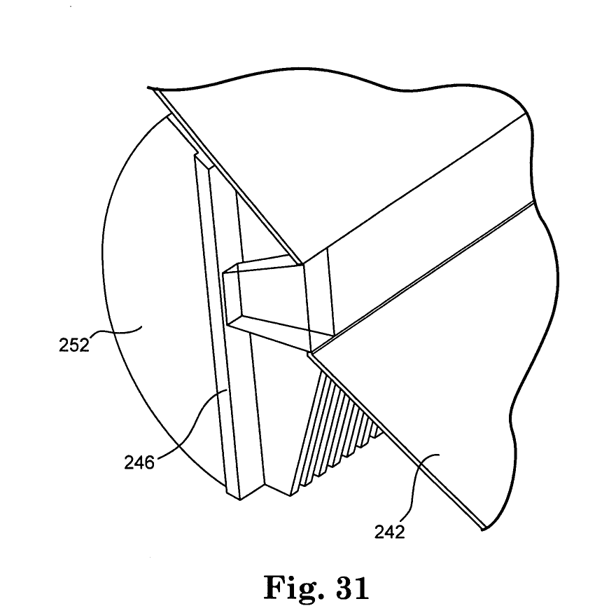

As an example, concentrator 238, as shown, comprises first optic system 240, second optic system 242, optional third optic system comprising optic 244 (see FIG. 30), heat spreader 246 and end caps 248. The heat spreader 246 is in thermal contact with the receiver 250 (see FIG. 30) and conducts excess thermal energy away from receiver 250 into the second optic system 242. Together second optic system 242 and end caps 248 provide convective surfaces by which the thermal energy is dissipated into the surrounding environment via convection. Preferably, as shown in FIG. 30, receiver 250 is positioned behind exit aperture of optic 244 and in thermal contact with heat spreader 246. In contemplated embodiments, the heat spreader 246 preferably interconnects at least one of: a) first optic system 240, b) second optic system 242, c) third optic system 244, d) receiver 250, or a combination thereof.

FIG. 30 illustrates exemplary fins 252 comprising plural parallel convective surfaces attached to the heat spreader 242. Fins 252 increase the area of convective surfaces in addition to that provided by the second optic system 242 and the end caps (not shown). Fins 252 preferably comprise one or more of the following: secondary concentrating elements, additional fins not part of concentrating elements or a combination thereof.

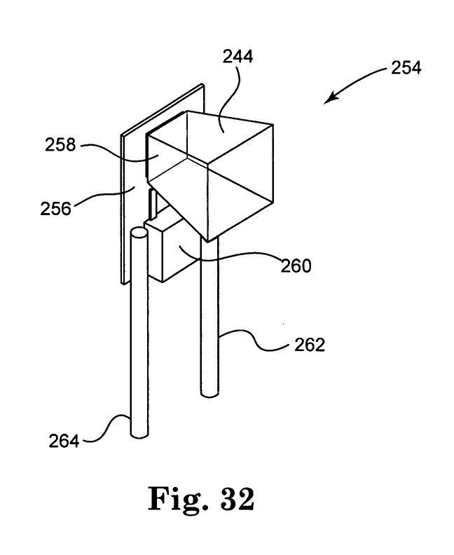

In FIG. 32 an exemplary receiver 254 shown with optic 244 and preferably includes a photovoltaic cell or device 256 on a substrate 258 with bypass diode 260. Leads 262 and 264 preferably provide electrical connection to receiver 254. In some embodiments, the photovoltaic cell 256 comprises a high efficiency cell including but not limited to triple junction GaAs cells. In some embodiments, receiver elements are arranged outside the volume bounded by the first and second optic systems.

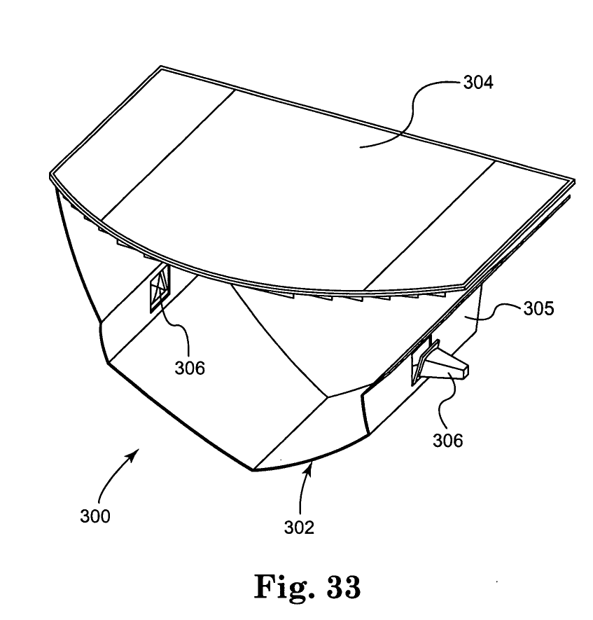

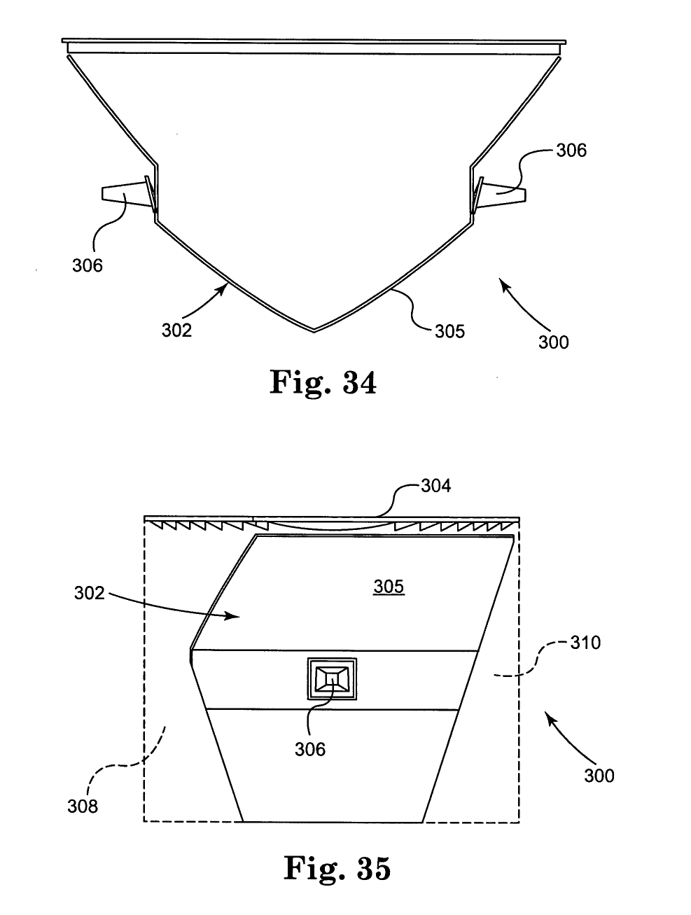

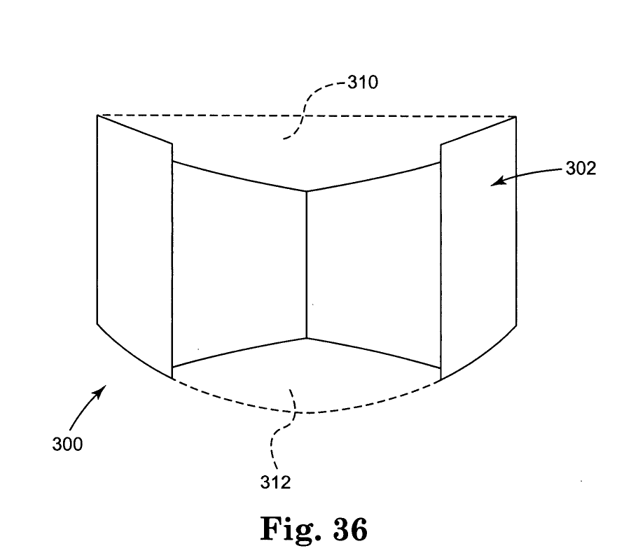

Another exemplary optical concentrator 300 in accordance with the present invention is shown in FIGS. 33-36. In FIG. 33 a perspective view is shown, in FIG. 34 and end view is shown, in FIG. 35 a side view is shown, and in FIG. 36 a top view is shown. Optical concentrator 300 may be designed according to optical concentrators described herein and preferably comprises body 302, first optic system 304 comprising one or more lenses, second optic system 305 comprising one or more reflective surfaces, and third optic system 306 comprising one or more optics.

Referring to the side view of FIG. 35 and the top view of FIG. 36, body 302 is preferably designed to only provide reflective surfaces where needed. That is, reflective surfaces are only provided where radiation is to be focused by first optic system 204. In particular, regions 308 and 310, which comprise regions beneath first optic system 304 are preferably not used. Such truncation results in a more compact design suitable for dense packing and articulation.

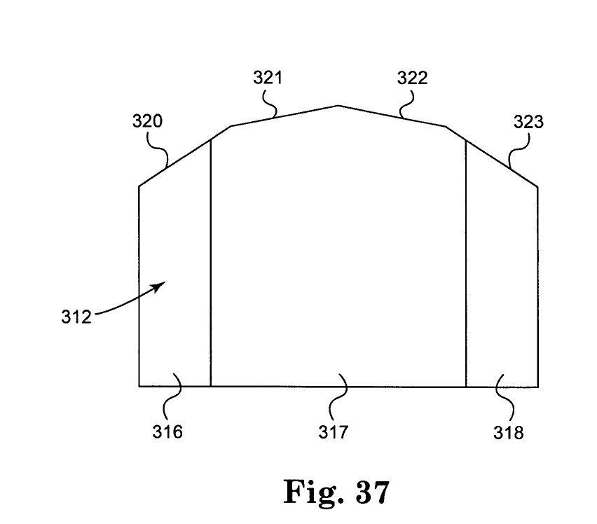

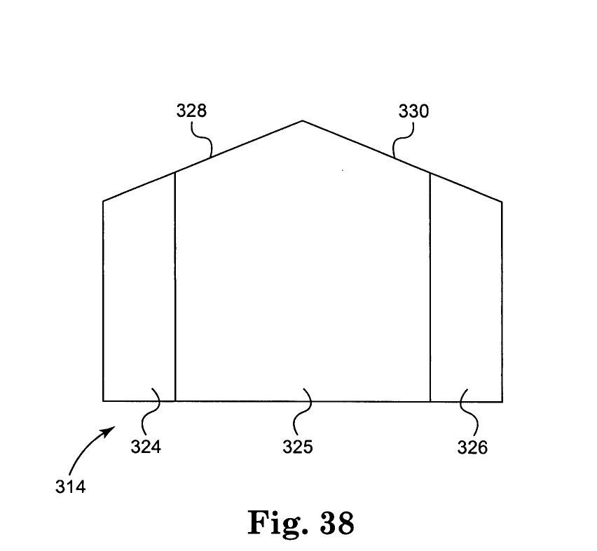

Alternate exemplary first optic systems, 312 and 314, are shown in FIGS. 37 and 38, respectively. First optic system 312, as shown, comprises plural lens components, 316, 317, and 318, and comprises an end defined by plural linear segments 320, 321, 322, and 322. Any number of linear segments can by used. Linear, radial, and/or arcuate segments can be used in any desired combination. Second optic system 314, as shown, comprise plural lens components, 324, 325, and 326, and comprises an end defined by plural linear segments 328 and 330. Any number of linear segments can by used. Linear, radial, and/or arcuate segments can be used in any desired combination.

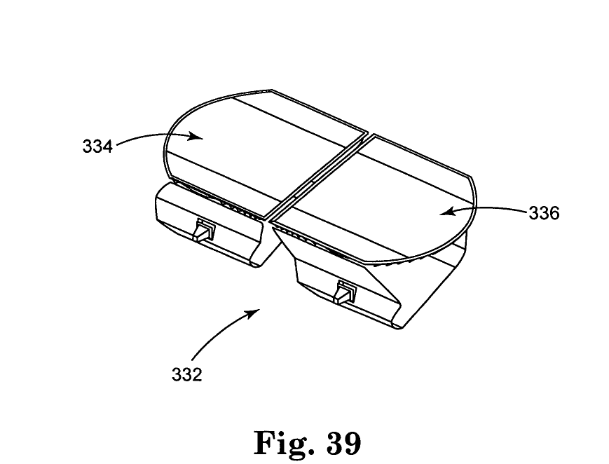

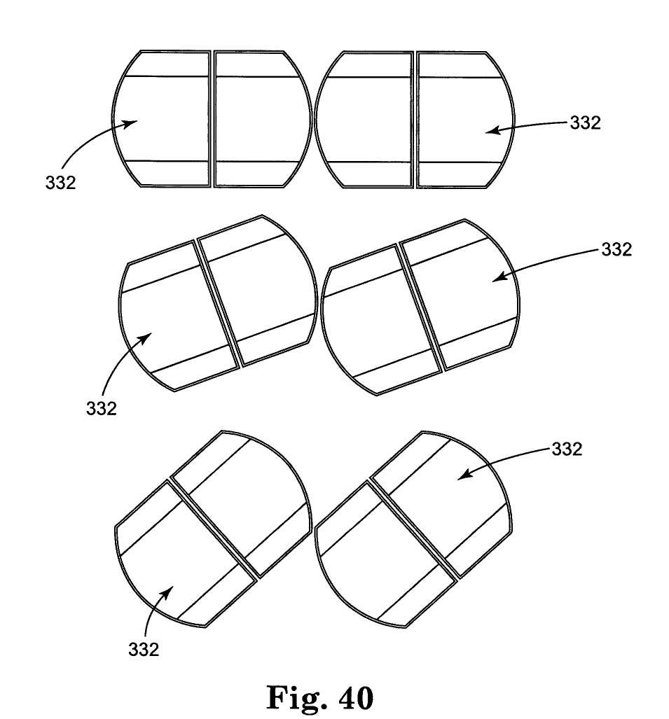

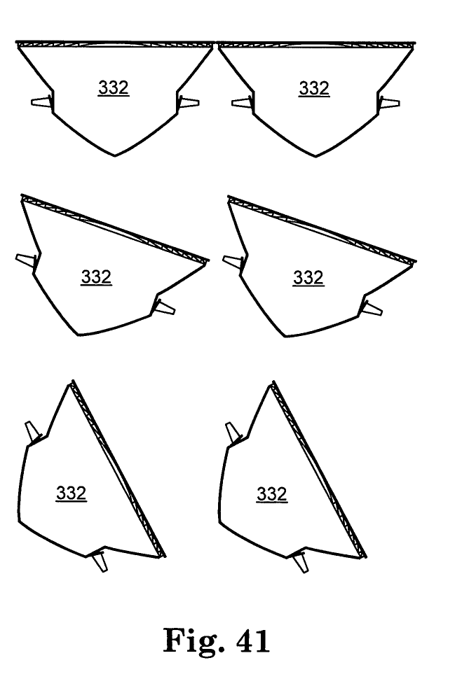

Optical concentrator 300 is particularly applicable for systems comprising plural arrayed optical concentrators because the design of exemplary optical concentrator 300 allows plural optical concentrators to be articulated in concert about two orthogonal axes with minimal spacing between adjacent concentrators. Referring to FIG. 39, optical concentrator system 332 is shown. System 332 comprises first and second optical concentrators, 334 and 336, respectively, arranged adjacent each other. Concentrators 334 and 336 are preferably similar to optical concentrator 300. In FIGS. 40 and 41, plural concentrator systems 332 are shown arranged in a regular array. In accordance with the present invention, concentrator systems 332 can be densely arranged and articulated in plural dimensions without collision. Such collision free articulation is provided by one or more of the arcuate ends of each system, trough shape of individual concentrators, and the truncated design of individual concentrators.

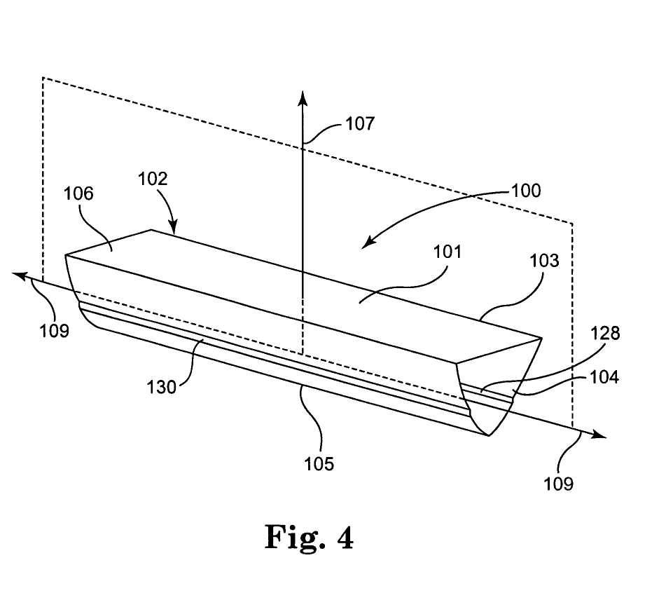

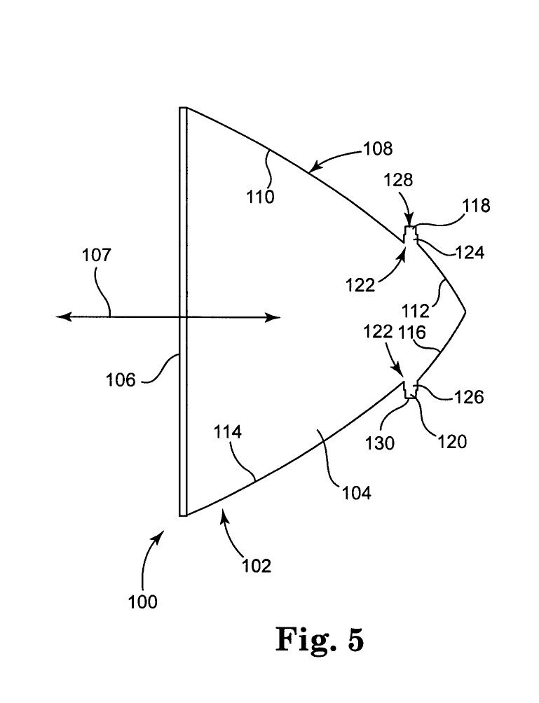

Another optical concentrator 100 in accordance with the present invention is illustrated in FIGS. 4 and 5 and comprises optical axis 107 and concentrating axis 109. A perspective view of optical concentrator 100 is shown in FIG. 4, and a cross-sectional view is shown in FIG. 5. Optical concentrator 100 comprises body 102 having entrance aperture 101 to internal space 104 and optional cover 106. At least a portion of internal space 104 provides a volume under optical concentration. Body 102 is often referred to as a trough or enclosure and comprises top 103 and bottom 105. Cover 106 functions to allow radiation to enter internal space 104 of body 102 where the light is concentrated and also functions to seal and protect body 102 from the surrounding environment. Cover 106 is preferably substantially transparent to the particular radiation desired to be concentrated and may comprise materials such as acrylic or glass, for example. Cover 106 may also include any desired lenses, optics, coatings, or the like but desirably does not serve as an optical concentrating element of concentrator 100 when the capturing of diffuse radiation for self-power is desired.

As illustrated, body 102 comprises first optic system 108 having reflective surfaces 110, 112, 114, and 116. Body 102 also includes first and second receivers, 118 and 120, respectively, that function to collect radiation, such as photovoltaic cells or the like. Body 102 also preferably comprises one or more second optics such as optional second optic system 122 having first optic 124 operatively positioned relative to first receiver 118 and second optic 126 operatively positioned relative to second receiver 120. Preferably, receiver 118 and first optic 124 of the second optic system 122 (if used) are positioned at a first discontinuity (or gap) 128 between reflective surface 110 and reflective surface 112. First discontinuity 128 functions as an exit aperture for concentrated radiation to leave internal space 104. Also, receiver 120 and second optic 126 of the second optic system 122 (if used) are positioned at a second discontinuity 130 between reflective surface 114 and reflective surface 116.

Surfaces 110, 112, 114, and 116 preferably comprise parabolic or parabolic-like surfaces. Preferably, the top surfaces 110 and 114 share a common foci with the bottom surfaces 112 and 116, respectively. Preferably, such foci are coincident or near coincident with the opposing side of the first optic. Contemplated parabolic surfaces may either be formed as a single element or may be formed as separate sub-elements. Contemplated first and second optic systems may be constructed of high-reflectivity, aluminum sheet metal manufactured by Alanod under the trade name MIRO™ (distributed by Andrew Sabel, Inc., Ketchum, Id.).

As mentioned, in some embodiments, first optic system comprises plural reflective surfaces, where such surfaces are preferably formed from one or more sub-elements, and may have parabolic profiles. In other embodiments, first optic system preferably comprises at least four parabolic surfaces including two on each side of the optical axis of the first optic system where such two surfaces are separated by a discontinuity or gap. Optical concentrators, such as those that provide high concentration preferably comprise a ratio between the input aperture and the receiver area greater than ten, preferably between 12 and 20.

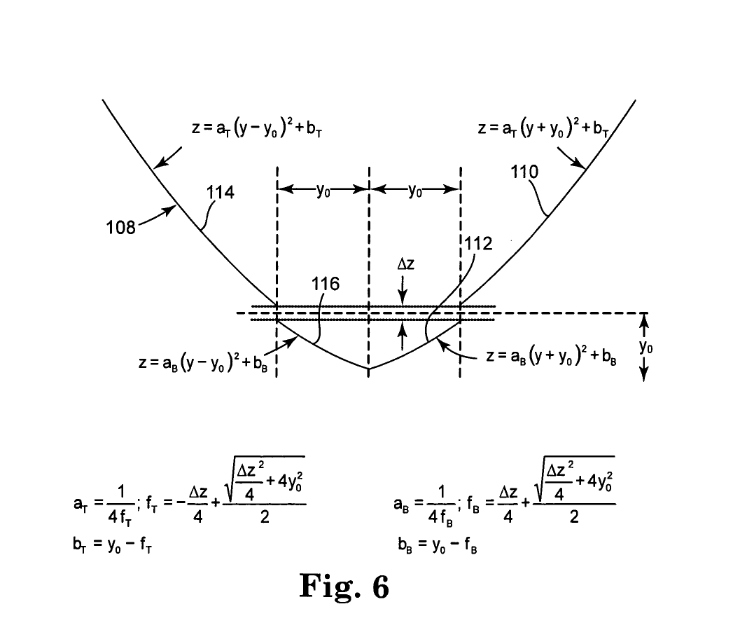

The first optic 108 of optical concentrator 100 is schematically shown in FIG. 6, and includes for purposes of illustration with respect to this embodiment parabolic surfaces 110, 112, 114, and 116 having general form:

z=a(y±y₀)²+t

### Where y₀ specifies the location of the respective foci (y₀,y₀) and (−y₀,y₀). Coefficients a and b of the above equation are a function of y₀ and the separation Δz 20 between the upper (110 and 114) and lower (112 and 116) surfaces.

$$\begin{matrix}{a}_{T} = \frac{1}{4 {f}_{T}} ; {f}_{T} = - \frac{Δ z}{4} + \frac{\sqrt{\frac{Δ {z}^{2}}{4} + 4 {y}_{0}^{2}}}{2} \\ {b}_{T} = {y}_{0} - {f}_{T} \\ {a}_{B} = \frac{1}{4 {f}_{B}} ; {f}_{B} = \frac{Δ z}{4} + \frac{\sqrt{\frac{Δ {z}^{2}}{4} + 4 {y}_{0}^{2}}}{2} \\ {b}_{B} = {y}_{0} - {f}_{B}\end{matrix}$$

In these forms, parabolic surfaces 114 and 116 focus rays parallel to the optical axis toward the focus located on the opposing side at (y₀,y₀), whereas the parabolic surfaces 110 and 112 focus parallel to the optical axis toward the focus located on the opposing side at (−y₀,y₀). It should be noted that the above equations illustrate one exemplary embodiment and that alternate embodiments result from perturbations to these general formulae.

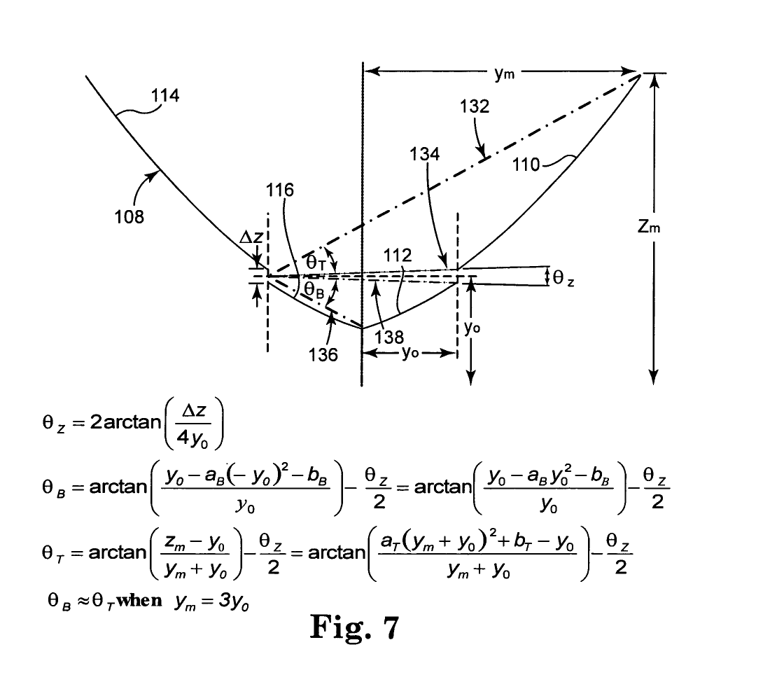

In FIG. 7, rays parallel to the optical axis incident on parabolic surface 110 form a ray bundle that has an angular spread θ_{T} defined by rays 132 and 134 reflected off the top and bottom extremity of the surface respectively. Similar rays incident on parabolic surface 112 form a ray bundle that has angular spread θ_{B} defined by rays 136 and 138 reflected off the top and bottom extremity of the surface respectively. The angle θ_{Z} represents an angular gap in the total ray bundle incident on the foci of the parabolic surfaces. In contemplated embodiments, these angles are specified by the following equations:

$$\begin{matrix}{θ}_{Z} = 2 arctan ( \frac{Δ z}{4 {y}_{0}} ) \\ {θ}_{B} = arctan ( \frac{{y}_{0} - {{a}_{B} ( - {y}_{0} )}^{2} - {b}_{B}}{{y}_{0}} ) - \frac{θ z}{2} \\ = arctan ( \frac{{y}_{0} - {a}_{B} {y}_{0}^{2} - {b}_{B}}{{y}_{0}} ) - \frac{θ z}{2} \\ {θ}_{T} = arctan ( \frac{{z}_{m} - {y}_{0}}{{y}_{ m} + {y}_{0}} ) - \frac{θ z}{2} \\ = arctan ( \frac{{{a}_{T} ( {y}_{m} + {y}_{0} )}^{2} + {b}_{T} - {y}_{0}}{{y}_{m} + {y}_{0}} ) - \frac{θ z}{2} \\ {θ}_{B} = {θ}_{T} when {y}_{m} = 3 {y}_{0 }\end{matrix}$$

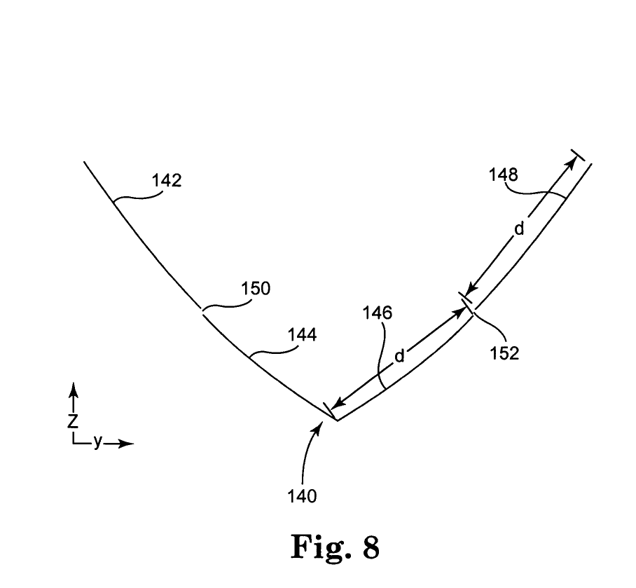

In FIG. 8, an exemplary first optic 140 for an optical concentrator in accordance with the present invention is schematically shown. First optic 140 includes reflective surfaces 142, 144, 146, and 148 as well as apertures 150 and 152. As illustrated, the location of each foci corresponds with apertures 150 and 152, respectively, and is centered along the respective trough wall so that the length of surface 142 is equal or near equal to the length of surface 144 and the length of surface 148 is equal or near equal to the length of surface 146. This arrangement has the advantage that it centers the thermal load along the trough wall. Reflective or refractive second optics can be used if desired.

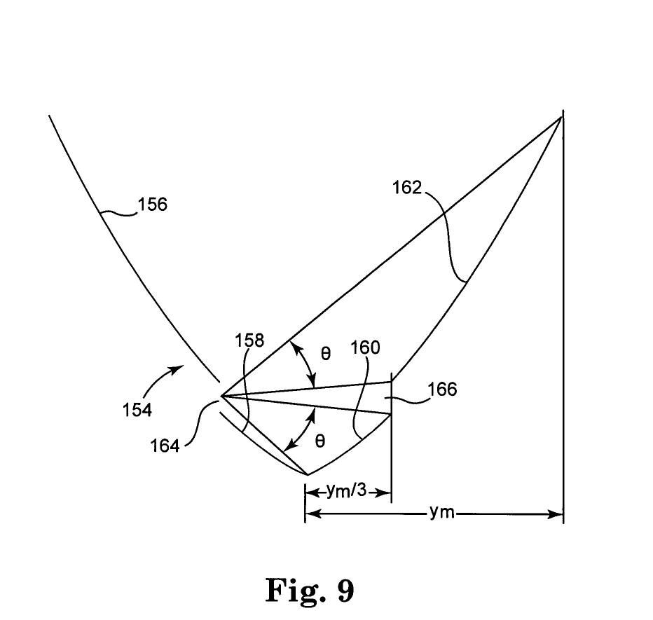

As an example, another exemplary first optic 154 for an optical concentrator in accordance with the present invention is schematically shown in FIG. 9. First optic 154 includes reflective surfaces 156, 158, 160, and 162 as well as apertures 164 and 166. As shown, the location of the foci is ⅓ of the trough width (y₀=yₘ/3). This arrangement has the advantage that the angular spread of incident rays from surface 156 or surface 162 is equal to the angular spread of incident rays from surface 158 or surface 160, respectively. Reflective or refractive second optics can be used if desired.

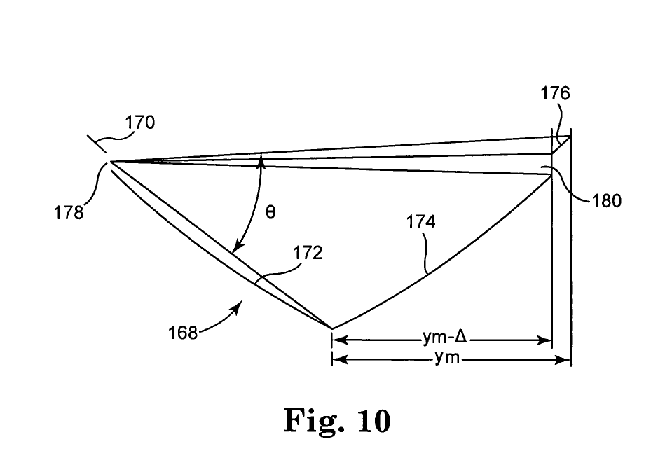

In FIG. 10, another exemplary first optic 168 for an optical concentrator in accordance with the present invention is schematically shown. First optic 168 includes reflective surfaces 170, 172, 174, and 176 as well as apertures 178 and 180. As shown, the location of the foci is near the top of the trough (y₀˜yₘ) and may be at the top of the trough. This arrangement has the advantage that it minimizes the total angular spread of incident rays and has a minimized height/width ratio. Reflective or refractive second optics can be used if desired.

The present invention has now been described with reference to several embodiments thereof. The entire disclosure of any patent or patent application identified herein is hereby incorporated by reference. The foregoing detailed description and examples have been given for clarity of understanding only. No unnecessary limitations are to be understood therefrom. It will be apparent to those skilled in the art that many changes can be made in the embodiments described without departing from the scope of the invention. Thus, the scope of the present invention should not be limited to the structures described herein, but only by the structures described by the language of the claims and the equivalents of those structures.

What is claimed is:

1. An optical concentrator, the optical concentrator comprising:
a body comprising a top and a bottom and comprising an entrance aperture that allows radiation to be concentrated to enter an interior space of the body, an exit that allows concentrated radiation to leave the interior space of the body, the exit positioned at an intermediate position between the top and bottom of the body, and a radiation receiver operatively positioned relative to and in optical communication with the exit;
a first concentrating optic comprising a first axis of concentration and plural line foci substantially parallel to the first axis of concentration; and
a second concentrating optic comprising a second axis of concentration substantially orthogonal to the first axis of concentration and a line focus substantially parallel to the second axis of concentration, and a reflective surface positioned within the interior space the body, wherein the line foci of the first and second concentrating optics cooperatively provide a region of focused radiation to the exit.

2. The optical concentrator of claim 1, wherein the region of focused radiation comprises a spot.

3. The optical concentrator of claim 1, wherein the body comprises a trough.

4. The optical concentrator of claim 1, wherein the radiation receiver comprises a photovoltaic cell.

5. The optical concentrator of claim 1, wherein the reflective surface comprises a parabolic surface.

6. The optical concentrator of claim 1, wherein the first concentrating optic comprises at least one fresnel lens.

7. The optical concentrator of claim 1, further comprising plural reflective surfaces.

8. The optical concentrator of claim 6, further comprising plural exits.

9. The optical concentrator of claim 1, further comprising a third concentrating optic operatively positioned at the exit and distinct from the first and second concentrating optics.

10. The optical concentrator of claim 9, wherein the third optic comprises a reflective optic.

11. The optical concentrator of claim 9, wherein the third optic comprises a refractive optic.

12. The optical concentrator of claim 1, further comprising a self-refrigeration device.

13. The optical concentrator of claim 12, wherein the self-refrigeration device comprises one or both of a heat spreader and a cooling fin.

14. The optical concentrator of claim 1, comprising an unobstructed light path between the entrance aperture and the radiation receiver.

15. An optical concentrator, the optical concentrator comprising:
a body comprising a top, bottom, first end, and second end, an exit that allows concentrated radiation to leave the interior space of the body, the exit positioned at an intermediate position between the top and bottom of the body, and a radiation receiver operatively positioned relative to and in optical communication with the exit;
a first concentrating optic comprising a first axis of concentration and plural line foci substantially parallel to the first axis of concentration, the first concentrating optic at least partially defining an entrance aperture that allows radiation to be concentrated to enter an interior space of the body; and
a second concentrating optic comprising a second axis of concentration substantially orthogonal to the first axis of concentration and a line focus substantially parallel to the second axis of concentration, and a reflective surface positioned within the interior space the body, wherein the line foci of the first and second concentrating optics cooperatively provide a region of focused radiation to the exit;
wherein one of the first and second ends of the body is truncated relative to the entrance aperture.

16. The optical concentrator of claim 15, wherein both of the first and second ends are truncated relative to the entrance aperture.

17. The optical concentrator of claim 15, in combination with and positioned relative to a second similar optical concentrator to provide an optical concentrator system.

18. The optical concentrator system of claim 17, in combination with and positioned relative to at least one similar optical concentrator system to form an array of optical concentrators systems.

19. A method of concentrating radiation in a solar concentrator, the method comprising the steps of:
causing solar radiation to impinge on a concentrating lens of an optical concentrator;
focusing the radiation with the concentrating lens to plural first line foci that impinge on a reflective surface of the optical concentrator;
focusing the radiation with the reflective surface to a second line focus orthogonal to first line foci; and
combining the first line foci and the second line focus to provide a spot focus to one or more receivers of the optical concentrator.

20. The method of claim 19, wherein the optical concentrator comprises any of the optical concentrators recited in claims 1-18.
